(19) United States
(12) Patent Application Publication
(10) Pub. No.: US 2016/0260679 A1
(43) Pub. Date: Sep. 8, 2016

(54) HYBRID INTERCONNECT FOR LOW TEMPERATURE ATTACH

(71) Applicant: Intel Corporation, Santa Clara, CA (US)

(72) Inventors: Kabirkumar J. Mirpuri, Scottsdale, AZ (US); Hongjin Jiang, Chandler, AZ (US); Tyler N. Osborn, Gilbert, AZ (US); Rajen S. Sidhu, Chandler, AZ (US); Ibrahim Bekar, Chandler, AZ (US); Susheel G. Jadhav, Chandler, AZ (US)

(73) Assignee: Intel Corporation, Santa, CA (US)

(21) Appl. No.: 14/430,131

(22) PCT Filed: Mar. 27, 2014
(86) PCT No.: PCT/US2014/032084

§ 371 Date: Mar. 20, 2015

(51) Int. Cl. H01L 23/00

(52) U.S. Cl. CPC H01L 24/73; H01L 24/05; H01L 24/92; H01L 24/13; H01L 24/29; H01L 2224/0401; H01L 2224/05147; H01L 2224/05573; H01L 2224/05655; H01L 2224/05664; H01L 2224/05644; H01L 2224/05647; H01L 2224/0569; H01L 2224/73104; H01L 2224/92143; H01L 2224/13014; H01L 2224/13026; H01L 2224/13111; H01L 2224/13139; H01L 2224/13147; H01L 2224/29026; H01L 2224/29109; H01L 2224/29113; H01L 2924/014

(57) ABSTRACT

Apparatuses, processes, and systems related to an interconnect with an increased z-height and decreased reflow temperature are described herein. In embodiments, an interconnect may include a solder ball and a solder paste to couple the solder ball to a substrate. The solder ball and/or solder paste may be comprised of an alloy with a relatively low melting point and an alloy with a relatively high melting point.

### FIELD

Embodiments of the present disclosure generally relate to the field of low temperature interconnects.

### BACKGROUND

Packages involving solder balls, and particularly solder balls disposed in a through-mold interconnect (TMI) may require a certain ball height in order to achieve the desired mold thickness for both room and high temperature warpage, while at the same time meeting ball height requirements. The height requirements may be based, for example, on height requirements for top memory packages attached to bottom system on chip (SoC) packages during surface mount processes.

In some cases, the packages may include a mold compound that is formed on a substrate of the package after disposition of the solder balls. The temperature and pressure of the molding process may result in deformation and/or collapse of the solder balls.

### BRIEF DESCRIPTION OF THE DRAWINGS

FIG. 1 depicts an example of a package with one or more interconnects, in accordance with various embodiments.

FIG. 2 depicts a more detailed example of an interconnect, in accordance with various embodiments.

FIG. 3 depicts an example of different ball heights both pre- and post-reflow in an interconnect, in accordance with various embodiments.

FIG. 4 depicts an example process for forming an interconnect on a substrate, in accordance with various embodiments.

FIG. 5 depicts an alternative example process for forming an interconnect on a substrate, in accordance with various embodiments.

FIG. 6 depicts an example process for forming an interconnect on a chip, in accordance with various embodiments.

FIG. 7 depicts an alternative example process for forming an interconnect on a chip, in accordance with various embodiments.

FIG. 8 depicts a generalized example for forming an interconnect, in accordance with various embodiments.

FIG. 9 schematically illustrates a computing device, in accordance with various embodiments.

### DETAILED DESCRIPTION

Embodiments of the present disclosure generally relate to the field of low temperature interconnects. In some embodiments, an interconnect may also be described as a “solder joint.” However, for the sake of consistency, herein the term “interconnect” will be used as a generalized term for interconnects, solder joints, or solder bumps.

In the following detailed description, reference is made to the accompanying drawings, which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the feature layer, and at least a part of the first feature may be in direct contact (e.g., direct physical and/or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application-specific integrated circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

Various Figures herein may depict one or more layers or elements of a chip, substrate, or interconnect. The elements depicted herein are depicted as examples of relative positions of the different elements. The elements are depicted for the purposes of explanation, and are not drawn to scale. Therefore, comparative sizes of elements should not be assumed from the Figures, and sizes, thicknesses, or dimensions may be assumed for some embodiments only where specifically indicated or discussed.

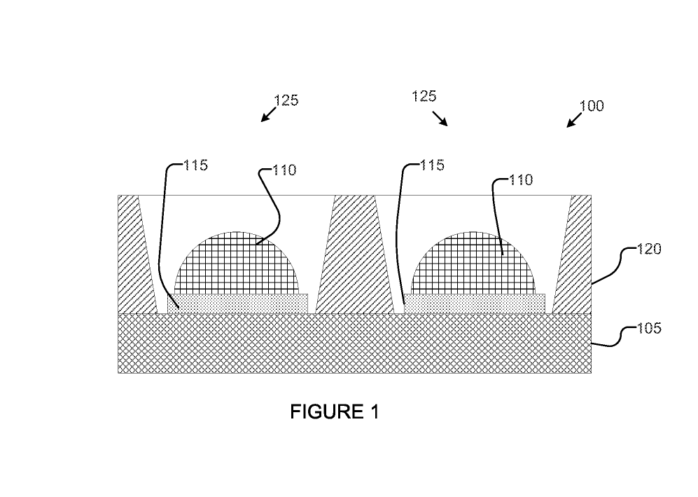

FIG. 1 depicts an example package 100. The package 100 includes a substrate 105, which may be an organic laminate or ceramic material. The package 100 may include one or more interconnects 110. The interconnects 110 may be coupled with pads 115 that are disposed on the substrate 105. In some embodiments, the pads 115 may be composed of copper, though in other embodiments the pads 115 may be composed of some other electrically or thermally conductive material such as nickel, gold, palladium, platinum, or alloys thereof. In some embodiments, the pads 115 may have a surface treatment or surface finish generally disposed on an outer surface of the pads 115 and positioned between the pads 115 and the interconnects 110. The surface finish may be composed of a material such as nickel, palladium, gold, copper, or an organic solderability preservative.

In some embodiments, the package 100 may further include a mold compound 120 generally disposed around, and laterally adjacent to, the interconnects 110 and/or the pads 115. The mold compound 120 may include one or more through-mold vias 125. The vias 125 may be formed in the mold compound 120 using one or more methods such as physical, chemical, or optical etching. In some embodiments the mold compound 120 may be extruded onto the substrate 105 such that it at least partially covers the interconnects 110, and then the vias 125 may be etched into the mold compound 120. In other embodiments, the mold compound 120 may be extruded onto the substrate 105 and the interconnects 110 may be protected, for example through use of a covering or other shielding element, such that the mold compound 120 does not cover the interconnects 110.

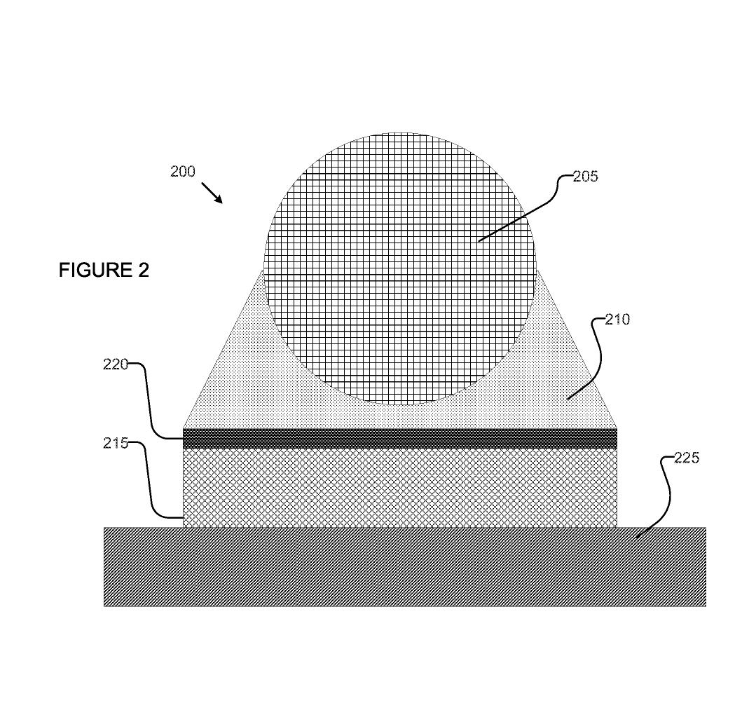

FIG. 2 depicts an example of an interconnect such as interconnect 110 in greater detail. Specifically, FIG. 2 depicts an interconnect 200, which may be similar to one of interconnects 110. The interconnect 200 is comprised of a solder ball 205 and a solder paste 210 generally positioned between the solder ball 205 and a pad 215, which may be similar to pad 115 of FIG. 1. In some embodiments, an inter-metallic compound (IMC) 220 may be generally positioned between the solder paste 210 and the pad 215, as will be explained in greater detail below. The pad 215 may be disposed on a substrate 225, which may be similar to substrate 105 of FIG. 1.

In some embodiments, the solder ball 205 may be constructed of an alloy including tin, silver, and copper (SAC). In other embodiments, the solder ball 205 may be an alloy of tin and antimony, off eutectic tin and copper, a SAC shell ball with a copper core, a SAC shell ball with a polymer core, or some other type of solder ball with a relatively high melting point as described in further detail below. In some embodiments the solder ball 205 may be lead-free. In some embodiments, the melting point of the solder ball 205 may be 217° Celsius. In other embodiments, the melting point of the solder ball 205 may be higher than 217° Celsius, for example 240° Celsius or higher. In other embodiments, the melting point of the solder ball 205 may be between approximately 180° Celsius and approximately 280° Celsius. As used herein, the melting point of the solder ball 205 or the alloy or material that comprises the solder ball 205 may be referred to as a “relatively high” melting point to distinguish the melting point of the solder ball 205 from a melting point of the solder paste 210 or a low-temperature solder (LTS) alloy as discussed below.

For example, in some embodiments the solder paste 210 may be an LTS alloy. For example, the LTS alloy may be, or include, an alloy of tin and bismuth (SnBi); tin, bismuth, nickel, and copper (SnBiNiCu); tin, bismuth, copper, and antimony (SnBiCuSb); tin, silver, and bismuth (SnAgBi); tin and indium (SnIn); tin, indium, and bismuth (SnInBi); or some other combination of bismuth and/or indium and some other alloy with a relatively low melting point as compared to the melting point of the solder ball 205. In some embodiments the solder paste 210 may be lead-free. In some embodiments the solder paste 210 may have a melting point of less than 200° Celsius, for example 175° Celsius, though in other embodiments the solder paste 210 may have a lower melting point or a melting point between approximately 120° Celsius and approximately 180° Celsius. In some embodiments, it may be desirable for the melting point of the solder paste 210 to be about 25° Celsius below that of the solder ball 205.

By using a solder paste 210 with a melting point that is lower than that of the solder ball 205, a reflow process of the interconnect 200 may be controlled such that the reflow temperature is above the melting point of the solder paste 210, but below that of the solder ball 205. Specifically, the reflow process may include heating the solder paste 210 and/or the solder ball 205 through direct application of an increased temperature and/or pressure such that the solder paste 210 and/or the solder ball 205 liquefies or melts. This liquefaction may result in the solder paste 210 and/or the solder ball 205 bonding with the substrate 225. For example, if a reflow process at 200° Celsius is performed, then the solder paste 210 may melt and chemically and/or physically bond with the pad 215, while the solder ball 205 may not significantly melt or otherwise deform. As a result, the interconnect 200 may have a greater z-height, measured as distance from the pad 215, than legacy interconnects. For example, the interconnect 200 may have a z-height of between 290 and 310 microns. This z-height may be approximately 32% to 41% higher than the z-height of legacy interconnects.

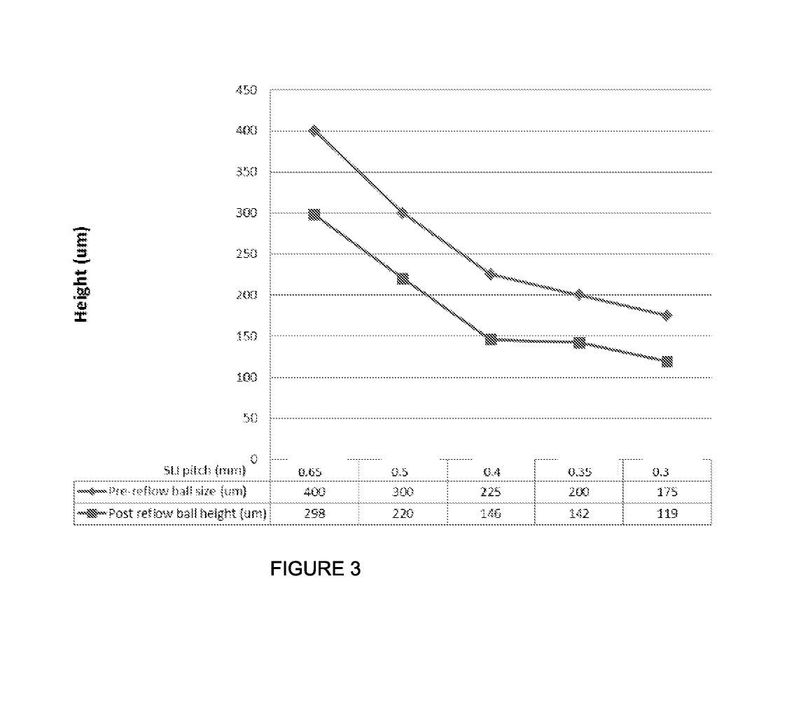

Turning briefly to FIG. 3, FIG. 3 depicts a comparison of post-reflow solder ball height correlation with pre-reflow solder ball diameter for one embodiment of a solder ball with a relatively high melting point, such as solder ball 205, and a solder paste with a relatively low melting point, such as solder paste 210. The embodiment of FIG. 3 assumes an approximately 21 micron solder resist (SR) thickness. In embodiments the SR may be an outermost layer of the substrate such as substrate 225. It can be seen that post-reflow solder ball height, as compared to pre-reflow solder ball diameter, may decrease by approximately 30% to 50% for a 0.3 millimeter to 0.65 millimeter pitch.

Returning to FIG. 2, in some embodiments, the solder paste 210 may be a combination of an LTS alloy, such as one or more of the LTS alloys described above such as SnBi, SnBiNiCu, etc., and an alloy with a relatively high melting point, such as the alloys described above with respect to solder ball 205. For example, in one embodiment, the solder paste 210 may comprise SnBi and SAC. In some embodiments, the solder paste 210 may comprise approximately equal amounts of SnBi and SAC, though in other embodiments the ratio of the two materials may vary.

The embodiment of a solder paste 210 comprised of approximately equal amounts of an LTS alloy and SAC may be desirable to use in the package 100 of FIG. 1. Specifically, as described above, the mold compound 120 may be extruded after the interconnects 110 are disposed on the substrate 105. However, in some embodiments the mold compound 120 may be extruded with pressure at a temperature from 165 to 175° Celsius, which may be close to the melting point of a solder paste such as solder paste 210 with a melting point of approximately 175° Celsius. Therefore, extrusion of the mold compound 120 may negatively affect the solder paste 210, for example by causing it to undesirably melt and collapse or otherwise deform.

However, use of a solder paste 210 comprised of an LTS alloy and SAC may reduce the amount of collapse or deformation. Specifically, the LTS alloy and the SAC may be deposited on the substrate 210 in powder form before a reflow process occurs. Then, as the temperature rises above the melting point of the LTS alloy, which may be approximately 175° Celsius as described above, the LTS alloy may melt and wet the SAC powder particles. As described above, the temperature of the interconnect 200 may rise, for example by reflow, mold extrusion, or some other process. Due to the interdiffusion of tin from the LTS alloy and the SAC, the overall metallurgical composition of the solder paste 210 post-reflow may no longer be the same, but instead may have a dominating influence on melting temperature due to the relatively higher amount of tin. In other words, the overall melting temperature of the solder paste 210 may be greater than 175° Celsius due to the combination of the LTS alloy and the SAC. The relatively higher melting temperature may therefore prevent or reduce the remelting of the solder paste 210 during the extrusion of the mold compound 120.

Additionally, during the extrusion of the mold compound 120, the LTS alloy of the solder paste 210 may melt and wet the solder ball 205. Additionally, the LTS alloy of the solder paste 210 may react with the metallization of the underlying pad 215, and particularly the surface finish of the pad 215, to form the IMC 220. The IMC 220 may be comprised of, for example, nickel, copper, tin, bismuth, or alloys thereof. The IMC 220 may serve to at least partially anchor the reflowed solder paste 210 and/or the solder ball 205 to the pad 215, thereby increasing the ability of the interconnect 200 to better resist the pressure associated with extrusion of the mold compound 120 at a temperature above the melting point of the LTS alloy.

In some embodiments, the melting temperature of a solder paste 210 that comprises both the LTS alloy and the SAC may be modulated dependent on the ratio of the LTS alloy to the SAC. Specifically, as the concentration of the SAC in the solder paste 210 increases, the melting point of the solder paste 210 may be further increased above the melting point of the LTS alloy. Additionally, as the concentration of the SAC in the solder paste 210 increases, the extent to which the solder paste 210 may collapse or otherwise deform during the mold extrusion process may decrease, which may result in a greater z-height of the interconnect 200.

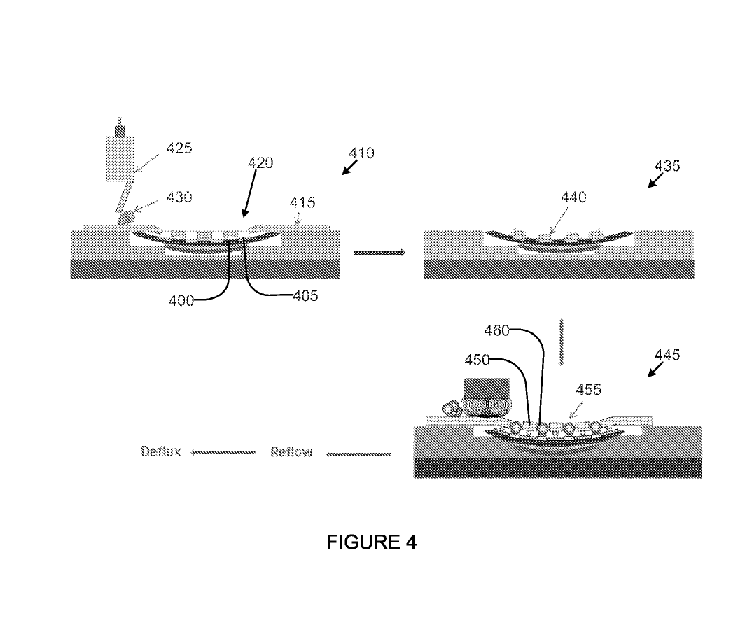

FIG. 4 depicts one example process of forming an interconnect such as interconnect 200 on substrate 225. Specifically, FIG. 4 depicts an example process for positioning one or more solder balls, such as solder balls 205, on a substrate, such as substrate 225. In some embodiments the process of FIG. 4 may be described as a controlled collapse chip connection (C4) bumping process, and the interconnects formed of the solder balls and solder paste may be referred to as first-level interconnects (FLIs). Specifically, a first-level interconnect may be an interconnect that couples a chip to a substrate or board such as a printed circuit board.

In embodiments, a substrate 400 with a plurality of pads 405, which may be similar to substrate 105 and pads 115 described above, may be positioned in a mold 410. The mold may include a stencil 415 with a plurality of openings 420. The mold 410 may be coupled with or otherwise disposed under a dispenser 425 configured to dispense LTS paste 430. The LTS paste 430 of FIG. 4 may be, in this embodiment, an LTS alloy such as SnBi or some other LTS alloy described above.

A print process may be performed at 435 such that the LTS paste 440, which may be similar to LTS paste 430, is deposited directly onto the pads 405 of the substrate 400 through the openings 420. The stencil 415 may then be removed. Next, a ball mount process may be performed at 445. The ball mount process may include positioning a second stencil 450 with a plurality of openings 455 over the LTS paste 440, pads 405, and substrate 400. One or more solder balls 460, which may be similar to solder ball 205, may be positioned within the openings 455 and directly over the LTS paste 440. In embodiments, the solder balls 460 may be comprised of an alloy with a relatively high melting point such as SAC, as discussed above.

The stencil 450 may be removed and a reflow process may be performed. In embodiments, the reflow process may include the application of temperature and/or pressure such that the temperature of the substrate 400, pads 405, LTS paste 440, and solder balls 460 is raised generally above a melting point of the LTS paste 440, but below a melting point of the solder balls 460. In some embodiments the reflow process may include extrusion of a mold compound such as mold compound 120 onto the substrate.

In some embodiments, the reflow process may be performed at a temperature higher than the melting point of the solder balls 460. In this embodiment, the reflow process may be performed before the stencil 450 is removed. The solder balls 460 and LTS paste 440 may melt during the reflow process and form hybrid LTS/SAC solder balls, that is, solder balls comprised of both an LTS alloy and SAC, on the pads 405 and/or substrate 400.

After the reflow process is performed, a deflux process may be performed. Specifically, any flux that was used in the process of FIG. 4 may be removed through electrical, optical, mechanical, or chemical means.

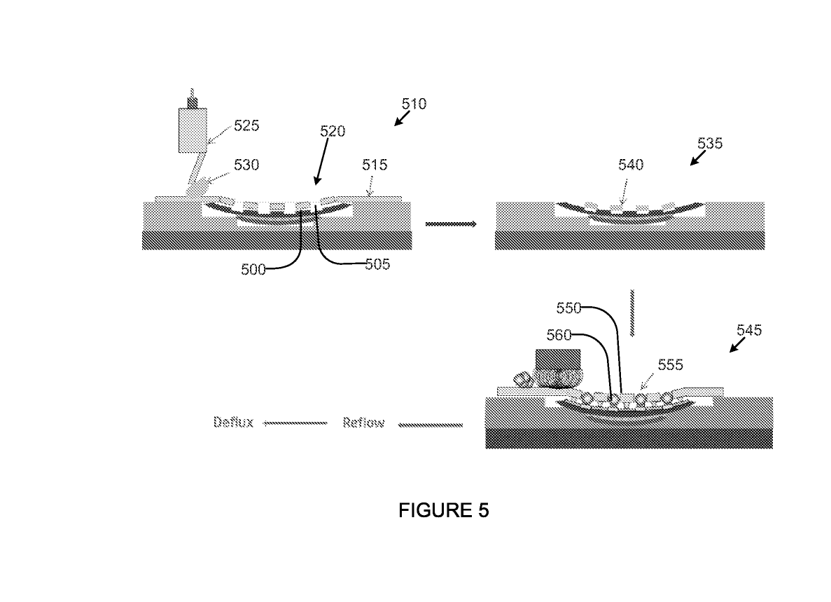

FIG. 5 depicts an alternative example process of positioning one or more solder balls such as solder balls 205 on a substrate such as substrate 225. In some embodiments the process of FIG. 5 may be described as a “micro bumping” process, and the interconnects formed of the solder balls and solder paste may be referred to as first-level interconnects, as described above.

In embodiments, a substrate 500 with a plurality of pads 505, which may be similar to substrate 400 and pads 405 described above, may be positioned in a mold 510. The mold may include a stencil 515 with a plurality of openings 520. The mold 510 may be coupled with or otherwise disposed under a dispenser 525 configured to dispense flux 530. The flux 530 may be comprised of, for example rosin, solvent, acid, amine, or a combination thereof.

A print process may be performed at 535 such that the flux 540, which may be similar to flux 530, is deposited directly onto the pads 505 of the substrate 500 through the openings 520. The stencil 515 may then be removed. Next, a ball mount process may be performed at 545. The ball mount process may include positioning a second stencil 550 with a plurality of openings 555 over the flux 540, pads 505, and substrate 500. One or more solder balls 560, which may be similar to solder ball 205, may be positioned within the openings 555 and directly over the flux 540. In some embodiments, the solder balls may be comprised of a mixture of an alloy with a relatively high melting point, for example SAC, and an alloy with a relatively low melting point, for example an LTS alloy such as SnBi, as discussed above.

The stencil 550 may be removed and a reflow process may be performed. In embodiments, the reflow process may be performed at a temperature that is generally above the melting point of the LTS alloy of the solder balls 560, but below the melting point of the SAC of the solder balls 560. As described above with respect to FIG. 2, the LTS alloy may melt and bond with the pads 505 and/or substrate 500, while the SAC does not melt or otherwise deform. In this process, the z-height of the interconnect formed of the solder balls 560 and pad 505 may be higher than if a solder ball comprised of only an LTS alloy was used.

After the reflow process is performed, a deflux process may be performed. Specifically, any flux that was used in the process of FIG. 5 may be removed through electrical, optical, mechanical, or chemical means.

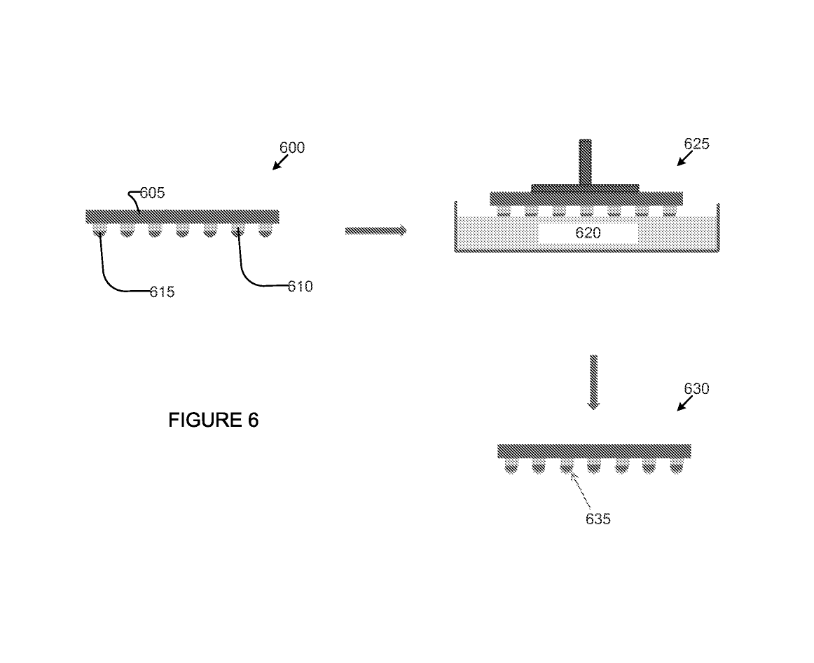

FIG. 6 depicts an example process to generate an interconnect having a combination of an alloy with a relatively high melting point such as SAC, and an LTS alloy with a relatively low melting point such as SnBi. The process of FIG. 6 may be used, for example, to generate an interconnect with a SAC/LTS hybrid structure for a chip to chip attach process. In some embodiments, the chip to chip attach process may be referred to as a local memory interconnect (LMI) process.

FIG. 6 depicts a chip 600, which may include a die 605. The die 605 may include a plurality of bumps 610, which may be copper or some other electrically conductive material or alloy. A solder 615 alloy with a relatively high melting point, for example SAC, may be deposited on the bumps 610. The chip 600, and particularly the bumps 610 and solder 615, may be dipped or otherwise submerged into a bath 620 of an alloy with a relatively low melting point, for example a bath 620 of an LTS alloy such as SnBi, at 625. In some embodiments, the dipping depth of the chip 600 may be controlled such that only the solder 615, or only a portion of the solder 615, is submerged into the bath 620. The chip 600 may then be removed from the molten bath 620 at 630. In some embodiments, the removal of the chip 600 may be at a controlled speed.

By submerging the solder 615 into the bath 620 at 625, the molten LTS alloy may wet the solder 615, which may result in the formation of a hybrid LTS/SAC alloy due to a strong surface tension and wetting force of the molten LTS alloy in the bath 620. Because the bath 620 may be molten LTS or some other alloy with a relatively low melting point, submersion of the SAC into the bath 620 may not cause the SAC to melt or otherwise deform. The chip 600 may therefore have a plurality of bumps or interconnects 635 comprised of a hybrid LTS/SAC alloy.

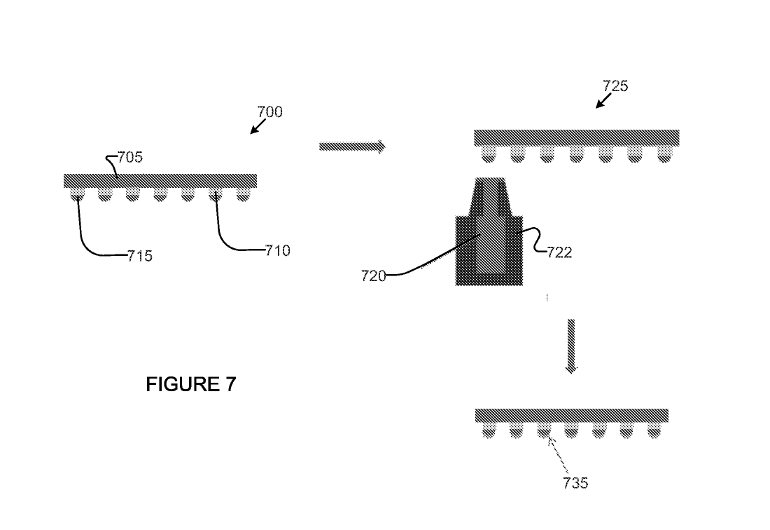

FIG. 7 depicts an alternative example of a process to generate an interconnect having a combination of an alloy with a relatively high melting point such as SAC, and an LTS alloy with a relatively low melting point such as SnBi. The process of FIG. 7 may also be used to generate an interconnect with a SAC/LTS hybrid structure for a chip to chip attach process, similarly to the process of FIG. 6.

Similarly to FIG. 6, FIG. 7 may include a chip 700 that includes a die 705 with a plurality of bumps 710 with solder 715 disposed on the bumps 710, which may be respectively similar to chip 600, die 605, bumps 610, and solder 615. In embodiments, the solder 715 may be comprised of an alloy with a relatively high melting point, for example SAC.

Rather than dip the solder 715 into a bath of molten LTS, as shown for example with respect to FIG. 6, the LTS 720 may be stamped onto the bumps 710, and specifically the solder 715, using a stamper 722 as shown at 725. The stamper 722 applying the LTS 720 may result in bumps or interconnects 735 comprised of a hybrid LTS/SAC alloy as described above with respect to interconnects 635.

The embodiments of FIGS. 4 through 7 may exhibit a variety of advantages. For example, a low temperature reflow process or a low temperature thermocomprossion bonding (TCB) process may be applied to FLIs or LMIs due to the relatively lower melting points for an interconnect comprising a hybrid LTS/SAC alloy. Because of the relatively low temperature reflow or bonding processes, post-chip attach package warpage and TCB process run rate may be improved. Additionally, for LMI processes, silica particle entrapment during an in-situ epoxy TCB process may be improved due to the LTS alloy melting at a relatively lower temperature. The LTS alloy may wet the pads of a chip, such as copper pads of a chip, which may repel silica particles off of the pads before the epoxy of the in-situ epoxy TCB process is cured, thereby restricting movement of the silica particles at high temperature.

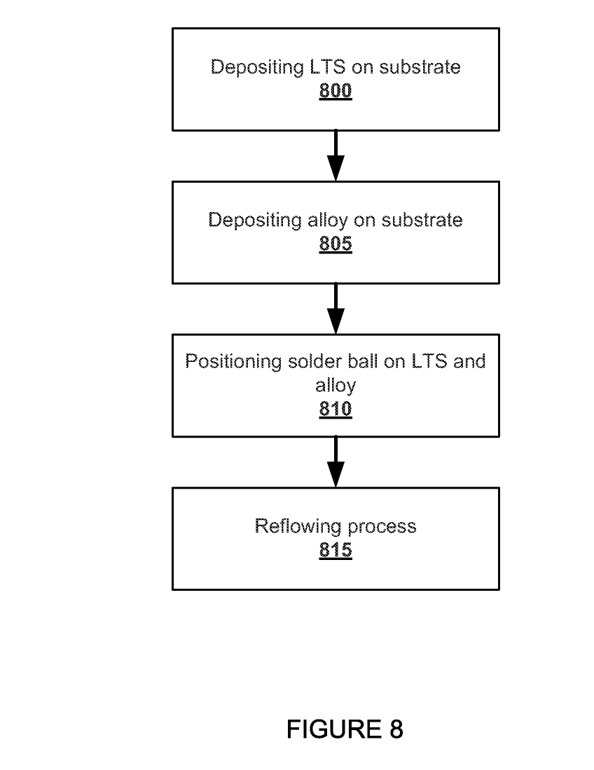

FIG. 8 depicts a generalized process for forming an interconnect such as interconnect 200 of FIG. 2. Specifically, an alloy with a relatively low melting point, for example an LTS alloy such as SnBi, may be deposited on a substrate such as substrate 225 at 800. Specifically, the LTS alloy may be deposited on a pad of the substrate such as pad 215.

Next, an alloy with a relatively high melting point, for example SAC, may be deposited on the substrate at 805. Specifically, the alloy may be deposited on the pad of the substrate. In some embodiments, elements 800 and 805 may be premixed and deposited on the substrate at substantially the same time. In some embodiments the alloy may be deposited on the substrate at 805 prior to the deposition of the LTS on the substrate at 800. In embodiments, the LTS alloy deposited at 800 and the SAC deposited at 805 may be the solder paste 210 of interconnect 200.

Next, a solder ball such as solder ball 205 is deposited on the LTS alloy and the SAC at 810. Finally, a reflow process may occur at 815. As described above, the reflow process may occur as the result of a mold compound extrusion process. In some embodiments, the reflow process may occur at a temperature at or above the melting point of the LTS alloy, but below the melting point of the SAC. As a result, the interconnect formed, for example interconnect 200, may have a z-height measured from the substrate that is higher than the z-height of some legacy interconnects.

It will be understood that the processes described above with respect to FIGS. 4 through 8 are only examples of how an interconnect such as interconnect 200 may be formed. In other embodiments, additional or alternative processes may be performed.

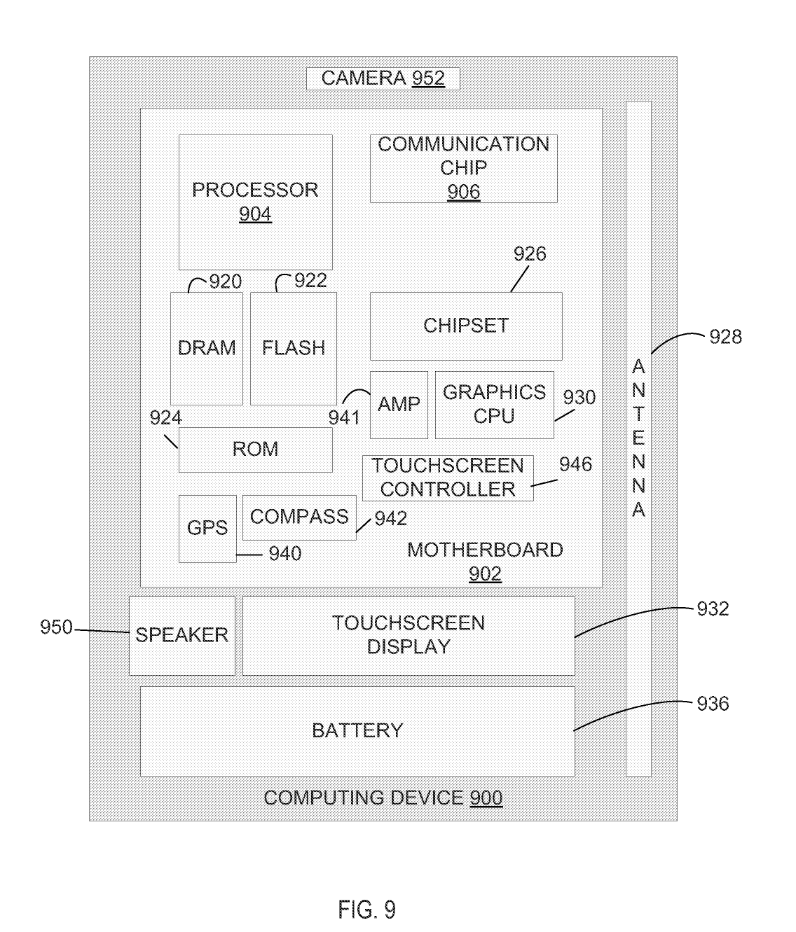

Embodiments of the present disclosure may be implemented into a system using any suitable hardware and/or software to configure as desired. FIG. 9 schematically illustrates a computing device 900 in accordance with one implementation of the invention. The computing device 900 may house a board such as motherboard 902. The motherboard 902 may include a number of components, including but not limited to a processor 904 and at least one communication chip 906. The processor 904 may be physically and electrically coupled to the motherboard 902. In some implementations, the at least one communication chip 906 may also be physically and electrically coupled to the motherboard 902. In further implementations, the communication chip 906 may be part of the processor 904. In some embodiments, the communication chip 906, the processor 904, or one or more of the other components of the computing device 900 may be coupled to one another using an interconnect such as interconnect 200 or another interconnect formed using one or more of the processes described above with respect to FIGS. 4 through 8.

Depending on its applications, computing device 900 may include other components that may or may not be physically and electrically coupled to the motherboard 902. These other components may include, but are not limited to, volatile memory (e.g., dynamic random access memory (DRAM)) 920, non-volatile memory (e.g., read-only memory (ROM)) 924, flash memory 922, a graphics processor 930, a digital signal processor (not shown), a crypto processor (not shown), a chipset 926, an antenna 928, a display (not shown), a touchscreen display 932, a touchscreen controller 946, a battery 936, an audio codec (not shown), a video codec (not shown), a power amplifier 941, a global positioning system (GPS) device 940, a compass 942, an accelerometer (not shown), a gyroscope (not shown), a speaker 950, a camera 952, and a mass storage device (such as hard disk drive, compact disk (CD), digital versatile disk (DVD), and so forth) (not shown). Further components, not shown in FIG. 9, may include a microphone, a filter, an oscillator, a pressure sensor, or an radio frequency identifier (RFID) chip.

The communication chip 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 906 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 906 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 906 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 906 may operate in accordance with other wireless protocols in other embodiments.

The computing device 900 may include a plurality of communication chips 906. For instance, a first communication chip 906 may be dedicated to shorter range wireless communications such as Wi-Fi and Bluetooth, and a second communication chip 906 may be dedicated to longer range wireless communications such as GPS, EDGE, GPRS, CDMA, WiMAX, LTE, EV-DO, and others.

The processor 904 of the computing device 900 may include a die in a package. The term “processor” may refer to any device or portion of a device that processes electronic data from registers and/or memory to transform that electronic data into other electronic data that may be stored in registers and/or memory.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data, for example an all-in-one device such as an all-in-one fax or printing device.

### Examples

Example 1 may include an apparatus comprising: a substrate having a pad disposed on the substrate; a solder ball coupled with the pad, the solder ball including an alloy of tin, silver, and copper; and a solder paste generally positioned between the pad and the solder ball, the solder paste including the alloy and a low-temperature solder (LTS) with a melting point that is less than or equal to a melting point of the alloy.

Example 2 may include the apparatus of example 1, wherein the pad comprises copper and has a surface finish of nickel, palladium, gold, copper, or an organic solderability preservative.

Example 3 may include the apparatus of example 1, wherein the alloy is a lead-free alloy.

Example 4 may include the apparatus of example 1, wherein the LTS comprises indium or bismuth.

Example 5 may include the apparatus of example 1, wherein the solder paste comprises approximately equal amounts of the alloy and the LTS.

Example 6 may include the apparatus of any of examples 1-5, further comprising: a mold compound coupled with the substrate and generally disposed laterally adjacent to, and generally surrounding, the solder ball and the solder paste.

Example 7 may include the apparatus of any of examples 1-5, further comprising an inter-metallic compound (IMC) disposed between the solder paste and the substrate.

Example 8 may include the apparatus of example 7, wherein the IMC comprises nickel, copper, tin, bismuth, or alloys thereof.

Example 9 may include the apparatus of any of examples 1-5, wherein the alloy has a melting point between approximately 180° Celsius and approximately 280° Celsius.

Example 10 may include the apparatus of example 9, wherein the solder paste has a melting point greater than or equal to 175° Celsius.

Example 11 may include a method comprising: depositing a solder paste on a pad of a substrate, the solder paste including a low-temperature solder (LTS) with a melting point that is less than or equal to 217° Celsius and an alloy of tin, silver, and copper; positioning a solder ball including the alloy on the solder paste such that the solder paste is disposed between the pad and the solder ball; and performing a reflow process at a temperature above the melting point of the LTS and below a melting point of the alloy.

Example 12 may include the method of example 11, wherein the LTS comprises indium or bismuth.

Example 13 may include the method of example 11, wherein the melting point of the alloy is between approximately 180° Celsius and approximately 280° Celsius.

Example 14 may include the method of any of examples 11-13, further comprising forming, during the low-temperature reflow process, an inter-metallic compound (IMC) between the solder ball and the pad, and directly adjacent to the pad.

Example 15 may include the method of any of examples 11-13, wherein the pad comprises copper.

Example 16 may include an apparatus comprising: a substrate with a first side and a second side, a die mounted on the first side and a pad disposed on the first side of the substrate; a mold compound coupled with the first side of the substrate, the mold compound having a through-mold via over the pad; a solder joint positioned within the through-mold via and coupled with the pad, the solder joint comprising: a solder ball comprised of a lead-free alloy; and a solder paste generally positioned between the substrate and the solder ball, the solder paste including generally equal amounts of the lead-free alloy and a low-temperature solder (LTS) having a melting point that is less than or equal to 175° Celsius, wherein the solder joint is configured to route electrical signals of the die.

Example 17 may include the apparatus of example 16, wherein the lead-free alloy comprises tin, silver, and copper.

Example 18 may include the apparatus of example 16, wherein the LTS comprises indium or bismuth.

Example 19 may include the apparatus of any of examples 16-18, wherein the lead-free alloy has a melting point of 217° Celsius.

Example 20 may include the apparatus of example 19, wherein the solder paste has a melting point greater than 175° Celsius.

Example 21 may include the apparatus of any of examples 16-18, wherein the pad comprises copper with a surface finish of nickel, palladium, gold, copper, or an organic solderability preservative.

Example 22 may include one or more non-transitory computer readable media comprising instructions to cause a computing device, upon execution of the instructions by one or more processors of the computing device, to perform the method of any of examples 11-15.

Various embodiments may include any suitable combination of the above-described embodiments, including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a substrate having a pad disposed on the substrate;
a solder ball coupled with the pad, the solder ball including an alloy of tin, silver, and copper; and
a solder paste generally positioned between the pad and the solder ball, the solder paste including the alloy and a low-temperature solder (LTS) with a melting point that is less than or equal to a melting point of the alloy.

2. The apparatus of claim 1, wherein the pad comprises copper and has a surface finish of nickel, palladium, gold, copper, or an organic solderability preservative.

3. The apparatus of claim 1, wherein the alloy is a lead-free alloy.

4. The apparatus of claim 1, wherein the LTS comprises indium or bismuth.

5. The apparatus of claim 1, wherein the solder paste comprises approximately equal amounts of the alloy and the LTS.

6. The apparatus of claim 1, further comprising:
a mold compound coupled with the substrate and generally disposed laterally adjacent to, and generally surrounding, the solder ball and the solder paste.

7. The apparatus of claim 1, further comprising an inter-metallic compound (IMC) disposed between the solder paste and the substrate.

8. The apparatus of claim 7, wherein the IMC comprises nickel, copper, tin, bismuth, or alloys thereof.

9. The apparatus of claim 1, wherein the alloy has a melting point between approximately 180° Celsius and approximately 280° Celsius.

10. The apparatus of claim 9, wherein the solder paste has a melting point greater than or equal to 175° Celsius.

11. A method comprising:
depositing a solder paste on a pad of a substrate, the solder paste including a low-temperature solder (LTS) with a melting point that is less than or equal to 217° Celsius and an alloy of tin, silver, and copper;
positioning a solder ball including the alloy on the solder paste such that the solder paste is disposed between the pad and the solder ball; and
performing a reflow process at a temperature above the melting point of the LTS and below a melting point of the alloy.

12. The method of claim 11, wherein the LTS comprises indium or bismuth.

13. The method of claim 11, wherein the melting point of the alloy is between approximately 180° Celsius and approximately 280° Celsius.

14. The method of claim 11, further comprising forming, during the low-temperature reflow process, an inter-metallic compound (IMC) between the solder ball and the pad, and directly adjacent to the pad.

15. The method of claim 11, wherein the pad comprises copper.

16. An apparatus comprising:
a substrate with a first side and a second side, a die mounted on the first side and a pad disposed on the first side of the substrate;
a mold compound coupled with the first side of the substrate, the mold compound having a through-mold via over the pad;
a solder joint positioned within the through-mold via and coupled with the pad, the solder joint comprising:
a solder ball comprised of a lead-free alloy; and
a solder paste generally positioned between the substrate and the solder ball, the solder paste including generally equal amounts of the lead-free alloy and a low-temperature solder (LTS) having a melting point that is less than or equal to 175° Celsius, wherein the solder joint is configured to route electrical signals of the die.

17. The apparatus of claim 16, wherein the lead-free alloy comprises tin, silver, and copper.

18. The apparatus of claim 16, wherein the LTS comprises indium or bismuth.

19. The apparatus of claim 16, wherein the lead-free alloy has a melting point of 217° Celsius.

20. The apparatus of claim 19, wherein the solder paste has a melting point greater than 175° Celsius.

21. The apparatus of claim 16, wherein the pad comprises copper with a surface finish of nickel, palladium, gold, copper, or an organic solderability preservative.
